(19) United States
(12) Patent Application Publication
(10) Pub. No.: US 2024/0153911 A1
(43) Pub. Date: May 9, 2024

(54) METHOD FOR FORMING SEMICONDUCTOR DEVICE AND SEMICONDUCTOR DEVICE FABRICATED THEREBY

(71) Applicant: WUHAN XINXIN SEMICONDUCTOR MANUFACTURING CO., LTD., Wuhan (CN)

(72) Inventors: Yu ZHOU, Wuhan (CN); Sheng HU, Wuhan (CN); Peng SUN, Wuhan (CN)

(21) Appl. No.: 18/086,105

(22) Filed: Dec. 21, 2022

(30) Foreign Application Priority Data
Nov. 4, 2022 (CN) 202211378614.4

(51) Int. Cl. H01L 25/065; H01L 21/768; H01L 23/00; H01L 25/00

(52) U.S. Cl. CPC H01L 25/0652; H01L 21/76898; H01L 24/08; H01L 24/80; H01L 25/50; H01L 2224/08145; H01L 2224/80895; H01L 2224/80896

(57) ABSTRACT

A method for forming a semiconductor device and a semiconductor device are disclosed. The method includes: forming a stacked chip assembly, and at least one of the stacked chip assembly is bonded to a surface of a package wafer by chip-to-wafer bonding; obtaining a first reconstructed wafer by performing wafer reconstruction through forming a first filling cap layer over surfaces of the package wafer and the stacked chip assembly(ies) on the package wafer. With this method, stacked chip assembly with chip-level dimension can be stacked with a package wafer with wafer-level dimension, thus enabling dense stacking of chips. In addition, other stacked chip assembly(ies) can be bonded to the first reconstructed wafer by chip-to-wafer bonding, resulting in even denser stacking of chips and high process efficiency and helping in reducing the process cost and shortening the manufacturing time. The semiconductor device can be fabricated using the method.

### CROSS-REFERENCE TO RELATED APPLICATION

This application claims the priority of Chinese patent application number 202211378614.4, filed on Nov. 4, 2022, the entire contents of which are incorporated herein by reference.

### TECHNICAL FIELD

The present invention relates to the field of semiconductor technology and, in particular to a method for forming a semiconductor device and a semiconductor device fabricated thereby.

### BACKGROUND

Since we have stepped into this era of information and data explosion, there has been a growing demand in the market for storage devices. Moreover, the demand for stacking chips of the same size to achieve a higher storage density is also growing day by day. A stacking technique enables vertical interconnection of multiple chips, which can result in a dramatically increased degree of integration by allowing multiple times more transistors to be included per unit area. Additionally, it can provide a shortened overall wiring length, faster interconnection, a reduced response time and lower energy consumption. Further, heterogeneous chips of different structures can be stacked together to provide sophisticated system functions.

In a known multi-chip stacking process, after individual chips to be stacked are obtained, micro-bumps are formed on one surface and under bump metallization (UBM) pads on another surface of each chip. The two surfaces are electrically connected by through-silicon vias (TSVs) in the chip. These chips are then assembled by stacking them one by one over a package wafer in such a manner that each chip is oriented with its surface with the micro-bumps facing downward to allow the micro-bumps to be connected to the UBM pads on the package wafer or an underlying chip.

However, with this multi-chip stacking process, it is very difficult to shorten the distance (pitch) between adjacent UBM pads (typically, it can be reduced at most to about 40 μm), leading to a limited number of connections that can be established per unit chip area. Moreover, in order to fabricate the UBM pads on the surfaces of the chips to be stacked, each chip must undergo processes of temporarily bonding a carrier substrate to the other surface before the pads are fabricated and removing the carrier substrate before the chip is stacked. This would increase the process cost and prolong the manufacturing process.

Therefore, there is still a need for an improved solution capable of dense stacking of chips with increased process reliability at reduced process cost.

### SUMMARY OF THE INVENTION

The present invention provides a method for forming a semiconductor device, which is capable of dense stacking of chips with increased process reliability at reduced process cost. The present invention also provides a semiconductor device.

In one aspect, the present invention provides a method for forming a semiconductor device, which comprises:
forming a stacked chip assembly comprising a plurality of chips stacked and interconnected in a direction of the thickness thereof;
providing a package wafer;
bonding at least one of the stacked chip assembly to a surface of the package wafer by performing a chip-to-wafer bonding process; and
obtaining a first reconstructed wafer by performing a wafer reconstruction process through forming a first filling cap layer over the surface of the package wafer and a surface of the stacked chip assembly on the package wafer, wherein the first reconstructed wafer comprises one layer of stacked chip assembly stacked on the package wafer.

Optionally, the method may further comprise:
repeating the chip-to-wafer bonding and the wafer reconstruction process over the first reconstructed wafer to stack more than two layers of stacked chip assembly on the package wafer.

Optionally, the formation of the stacked chip assembly may comprise: forming a wafer stack by stacking and interconnecting a plurality of device wafers; and obtaining the stacked chip assembly by dicing the wafer stack in a direction of a thickness thereof.

Optionally, each device wafer in the wafer stack may have a front side, on which electronic an component is formed, and a back side opposite to the front side, wherein the front side of each device wafer is oriented in a same direction.

Optionally, the wafer stack may comprise a first device wafer, a second device wafer, . . . , and an n-th device wafer, which are stacked sequentially in a direction of a thickness thereof, where n is an integer equal to or greater than 2, wherein each of the first, second, . . . , and n-th device wafers comprises interconnect structures on the front side thereof and a bond structure connected to the interconnect structures on the front side, wherein each of the second, . . . , n-th device wafers further comprises interconnect structures on the back side thereof and a bond structure connected to the interconnect structures on the back side, and wherein between adjacent device wafers, the bond structure on the front side of one of the adjacent device wafers is bonded and electrically connected to the bond structure on the back side of the other of the adjacent device wafers.

Optionally, bonding an m-th device wafer to an (m−1)-th device wafer may comprise:
bonding a carrier substrate to the front side of the m-th device wafer;
thinning the m-th device wafer from the back side;
forming TSVs in the m-th device wafer from the back side;
forming, on the back side of the m-th device wafer, the interconnect structures and the bond structure connected to the interconnect structures, wherein the TSVs connect the interconnect structures on the front side to the interconnect structures on the back side of the m-th device wafer;
bonding the back side of the m-th device wafer to the front side of the (m−1)-th device wafer; and
removing the carrier substrate, where m is equal to or greater than 2 and equal to or smaller than n.

Optionally, the first device wafer may be thinned from the back side before the wafer stack is diced.

Optionally, bonding each stacked chip assembly to the package wafer may be accomplished by bonding the bond structure on the front side of the n-th device wafer to the package wafer.

Optionally, the method may further comprise:
forming, in the back side of a part of the first device wafer in the first reconstructed wafer, TSVs connected to interconnect structures on the front side of the part of the first device wafer; and
forming, on the back side of the part of the first device wafer, a bond structure with a wafer-level dimension and connected to the TSVs, in order to allow stacking of the other layer of stacked chip assembly on the side of the first reconstructed wafer away from the package wafer by the chip-to-wafer bonding.

Optionally, the method may further comprise, subsequent to the stacking of the at least one stacked chip assembly(on the package wafer, forming metal solder pads on a side of the package wafer away from the stacked chip assembly.

In another aspect, the present invention provides a semiconductor device comprising:
a package substrate;
at least one layer of stacked chip assembly stacked on the package substrate, wherein each layer of stacked chip assembly comprises at least one stacked chip assembly, and wherein each stacked chip assembly comprises a plurality of chips stacked and interconnected in a direction of a thickness thereof; and
at least one filling cap layer each surrounding a corresponding layer of stacked chip assembly.

Optionally, the semiconductor device may comprise at least two layers of stacked chip assembly stacked on the package substrate, wherein adjacent layers of stacked chip assembly are bonded by an inter-assembly bond structure.

Optionally, the stacked chip assembly comprises a first chip, a second chip, . . . , and an n-th chip, which are stacked sequentially in a direction of a thickness thereof, where n is an integer equal to or greater than 2, wherein each of the first, second, . . . , and n-th chips comprises interconnect structures on the front side thereof and an inter-chip bond structure connected to the interconnect structures on the front side, wherein each of the second, . . . , and n-th chips further comprises interconnect structures on the back side thereof and an inter-chip bond structure connected to the interconnect structures on the back side, and wherein between adjacent chips, the inter-chip bond structure on the front side of one of the adjacent chips is bonded and electrically connected to the inter-chip bond structure on the back side of the other one of the adjacent chips.

Optionally, each of the inter-chip and inter-assembly bond structures comprises a dielectric layer and a plurality of metal bond pads formed in the dielectric layer.

Optionally, the inter-assembly bond structure is of a wafer-level dimension, and in adjacent layers of stacked chip assembly, the layer of stacked chip assembly located closer to the package substrate and the corresponding filling cap layer surrounding thereof are covered by the inter-assembly bond structure.

In the method provided in the present invention, a stacked chip assembly comprising a plurality of chips stacked and interconnected in the direction of the thickness thereof is first formed, and at least one of the stacked chip assembly is bonded to a package wafer by chip-to-wafer bonding. Additionally, a first reconstructed wafer is obtained by performing wafer reconstruction through forming a first filling cap layer over surfaces of the package wafer and the stacked chip assembly(ies) on the package wafer. With this method, stacked chip assembly(ies) with chip-level dimensions can be stacked with a package wafer with wafer-level dimensions. This enables dense stacking of chips with high process reliability and helps reduce the process cost. In addition, other stacked chip assembly(ies) can be bonded to the first reconstructed wafer by chip-to-wafer bonding, resulting in even denser stacking of chips and high process efficiency and helping in reducing the process cost and shortening the manufacturing time.

The semiconductor device provided in the present invention includes a package substrate and at least one layer of stacked chip assembly(ies) stacked on the package substrate. In each layer, the stacked chip assembly(ies) is/are surrounded by a filling cap layer. The package substrate may have wafer- or chip-level dimensions. In addition to enabling dense stacking of chips, this helps reduce the process cost and shorten the manufacturing time.

### BRIEF DESCRIPTION OF THE DRAWINGS

FIG. 1 is a flowchart of a method for forming a semiconductor device according to an embodiment of the present invention.

FIG. 2 schematically shows in a cross-sectional view how a first device wafer and a second device wafer bonded together in a method for forming a semiconductor device according to an embodiment of the present invention.

FIG. 3 is a schematic cross-sectional view of a wafer stack formed in a method for forming a semiconductor device according to an embodiment of the present invention.

FIG. 4 is a schematic cross-sectional view of a structure formed after a wafer stack is thinned in a method for forming a semiconductor device according to an embodiment of the present invention.

FIG. 5 is a schematic cross-sectional view of a structure formed after a wafer stack is transferred onto a dicing frame in a method for forming a semiconductor device according to an embodiment of the present invention.

FIG. 6 is a schematic cross-sectional view of a structure formed after a wafer stack is diced to produce individual stacked chip assembly(ies) in a method for forming a semiconductor device according to an embodiment of the present invention.

FIG. 7 is a schematic cross-sectional view of a structure formed after a package wafer is bonded to a carrier substrate in a method for forming a semiconductor device according to an embodiment of the present invention.

FIG. 8 is a schematic cross-sectional view of a structure formed after at least one stacked chip assembly is bonded to a surface of a package wafer in a method for forming a semiconductor device according to an embodiment of the present invention.

FIG. 9 is a schematic cross-sectional view of a structure formed after a first filling cap layer is formed in a method for forming a semiconductor device according to an embodiment of the present invention.

FIG. 10 is a schematic cross-sectional view of a structure formed after at least one stacked chip assembly is bonded to a surface of a first reconstructed wafer in a method for forming a semiconductor device according to an embodiment of the present invention.

FIG. 11 is a schematic cross-sectional view of a structure formed after a second filling cap layer is formed in a method for forming a semiconductor device according to an embodiment of the present invention.

FIG. 12 is a schematic cross-sectional view of a structure formed after a carrier substrate is bonded to a topmost layer of stacked chip assembly(ies) in a method for forming a semiconductor device according to an embodiment of the present invention.

FIG. 13 is a schematic cross-sectional view of a structure formed after metal solder pads are formed on the side of a package wafer away from stacked chip assembly(ies) in a method for forming a semiconductor device according to an embodiment of the present invention.

In these figures,

110: a first dielectric layer; 120, first metal bond pads; 130, a second dielectric layer; 140, second metal bond pads; 150, a third dielectric layer; 160, third metal bond pads; 200, a package wafer; 300, a first filling cap layer; 400, a second filling cap layer; 500, metal solder pads; 10, 11, 12, 13, carrier substrates; 20, 40, 50, TSVs; and 30, a dicing frame.

### DETAILED DESCRIPTION

The proposed method and semiconductor device will be described in greater detail below by way of specific embodiments with reference to the accompanying drawings. From the following description, advantages and features of the invention will become more apparent. It is to be understood that the figures are provided in a very simplified form not necessarily drawn to exact scale for the only purpose of facilitating easy and clear description of the embodiments.

Embodiments of the present invention include a method for forming a semiconductor device. This method will be further explained below with reference to FIGS. 1 to 13.

Referring to FIG. 1, in step S1, a stacked chip assembly is formed, which includes a plurality of stacked and interconnected chips. The number of stacked chips in the stacked chip assembly may be specifically configured depending on the design of the semiconductor device and the capabilities of the process used. In some embodiments, the formation of the stacked chip assembly includes: forming a wafer stack by stacking and interconnecting a plurality of device wafers; and then obtaining the stacked chip assembly by dicing the wafer stack in the direction of the thickness thereof.

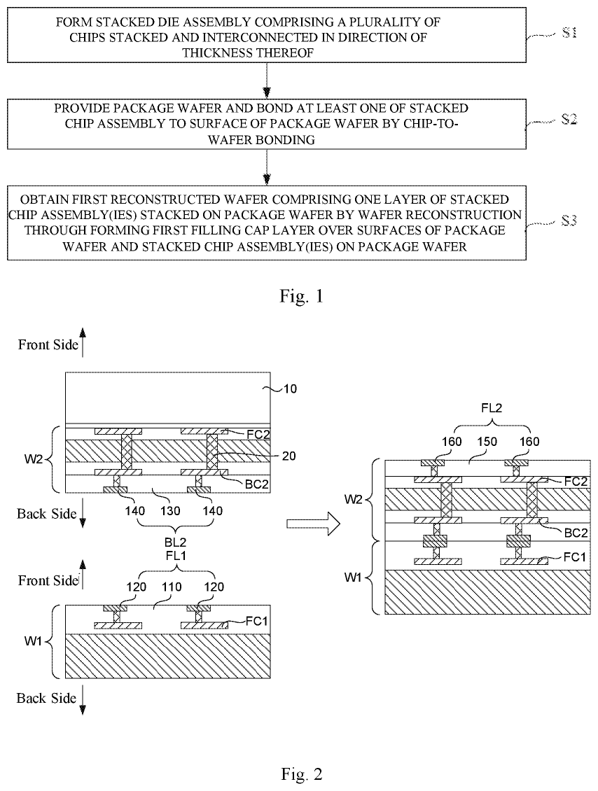

The device wafers in the wafer stack may include electronic components formed by semiconductor processes, which may be interconnected as a result of the interconnection of the plurality of device wafers. As an example, the device wafers may include storage devices, such as nonvolatile memory devices or random access memory devices. Examples of the nonvolatile memory devices may include, among others, NOR flash memory, NAND flash memory, ferroelectric memory and phase-change memory devices. The device wafers may further include other types of active or passive devices. In the embodiment shown in FIG. 2, the wafer stack includes a first device wafer W1 and a second device wafer W2. Each device wafer may have a front side on which electronic components are formed and a back side opposite to the front side. During the formation of the wafer stack, as required, the front side of one device wafer may be oriented toward and bonded to the front side of another device wafer, and/or the front side of one device wafer may be oriented toward and bonded to the back side of another device wafer. In some embodiments, in the formed wafer stack, the front sides of all the device wafers are oriented in the same direction.

Specifically, the wafer stack may include, sequentially stacked in the direction of the thickness thereof, a first device wafer W1, a second device wafer W2, . . . , an n-th device wafer Wn, where n is an integer that is equal to or greater than 2. During the formation of the wafer stack, for example, the back side of the second device wafer W2 may be bonded to the front side of the first device wafer W1, then the front side of the second device wafer W2 to the back side of the third device wafer W3, and so forth, until the front side of the (n−1)-th device wafer Wn−1 is bonded to the back side of the n-th device wafer Wn. Optionally, n may be equal to or smaller than 12.

Referring to FIG. 2, for example, the first device wafer W1 may have interconnect structures FC1 formed on its front side, and the second device wafer W2 may have interconnect structures FC2 formed on its front side. The interconnect structures FC1 and FC2 may include patterned metal layers (e.g., redistribution layers (RDLs)) isolated by a dielectric material, and conductive plugs connecting adjacent metal layers. The metal layers and conductive plugs can provide connections between various doped regions, circuits and input/output ports on the device wafers. The interconnect structures FC1 and FC2 may have different connection configurations. For the sake of clarity, only a part of metal layers in the interconnect structures FC1 and FC2 are shown in FIG. 2.

Before the front side of the first device wafer W1 is bonded to the back side of the second device wafer W2, the front side of the second device wafer W2 may be temporarily bonded to a carrier substrate 10 (e.g., adhesive or fusion bonding), and the second device wafer W2 may be then thinned from the back side, followed by a through-silicon via (TSV) process performed on the back side of the second device wafer W2, by which TSVs 20 connected to the interconnect structures FC2 are formed in the second device wafer W2. As required, interconnect structures BC2 may be formed on the back side of the second device wafer W2. The interconnect structures BC2 may include patterned metal layers (e.g., redistribution layers (RDLs)) isolated by a dielectric material, and conductive plugs connecting adjacent metal layers. For the sake of clarity, only a part of metal layers in the interconnect structures BC2 are shown in FIG. 2. In addition, prior to the bonding process, a bond structure FL1 connected to the interconnect structures FC1 may be formed on the front side of the first device wafer W1, and a bond structure BL2 connected to the interconnect structures BC2 on the back side of the second device wafer W2. In the bonding process, the first device wafer W1 and the second device wafer W2 are stacked and interconnected together by bonding the bond structure FL1 to the bond structure BL2. The bond structure FL1 may include a first dielectric layer 110 covering the interconnect structures FC1 and first metal bond pads 120 formed within the first dielectric layer 110. The first metal bond pads 120 may be connected by respective conductive plugs to the interconnect structures FC1. The bond structure BL2 may include a second dielectric layer 130 covering the interconnect structures BC2 and second metal bond pads 140 formed within the second dielectric layer 130. The second metal bond pads 140 may be connected by respective conductive plugs to the interconnect structures BC2. The bonding of the bond structure FL1 to the bond structure BL2 may be accomplished by hybrid bonding so that: the first dielectric layer 110 is bonded to the second dielectric layer 130 or the second metal bond pads 140 opposite thereto; and the first metal bond pads 120 are bonded to the second metal bond pads 140 or the second dielectric layer 130 opposite thereto. Bonding the first metal bond pads 120 to the second metal bond pads 140 opposite thereto results in interconnection of the first device wafer W1 and the second device wafer W2.

Referring to FIG. 2, after the second device wafer W2 is stacked with the first device wafer W1, the carrier substrate 10 may be removed, exposing the front side of the second device wafer W2. Additionally, when a relatively large number of device wafers are to be stacked, a bond structure FL2 may be formed on the exposed front side of the second device wafer W2. The bond structure FL2 may include a third dielectric layer 150 formed on the front side of the second device wafer W2 and third metal bond pads 160 formed within the third dielectric layer 150. The third metal bond pads 160 may be connected by respective conductive plugs to the interconnect structures FC2. Subsequently, similar processes may be carried out to sequentially stack the third device wafer W3, the fourth device wafer W4, . . . , the n-th device wafer Wn over the front side of the second device wafer W2. In these processes, bonding the m-th device wafer (where m is equal to or greater than 2 and equal to or smaller than n) to the (m−1)-th device wafer may include: at first, bonding the front side of the m-th device wafer to a carrier substrate; then thinning the m-th device wafer from the back side; subsequently, forming TSVs in the m-th device wafer from the back side; after that, forming respective interconnect structures on the back side of the m-th device wafer and a bond structure connected to the interconnect structure, wherein the TSVs connect interconnect structures on the front side of the m-th device wafer to the interconnect structures on the back side thereof; thereafter, bonding the back side of the m-th device wafer to the front side of the (m−1)-th device wafer; and next, removing the carrier substrate from the front side of the m-th device wafer.

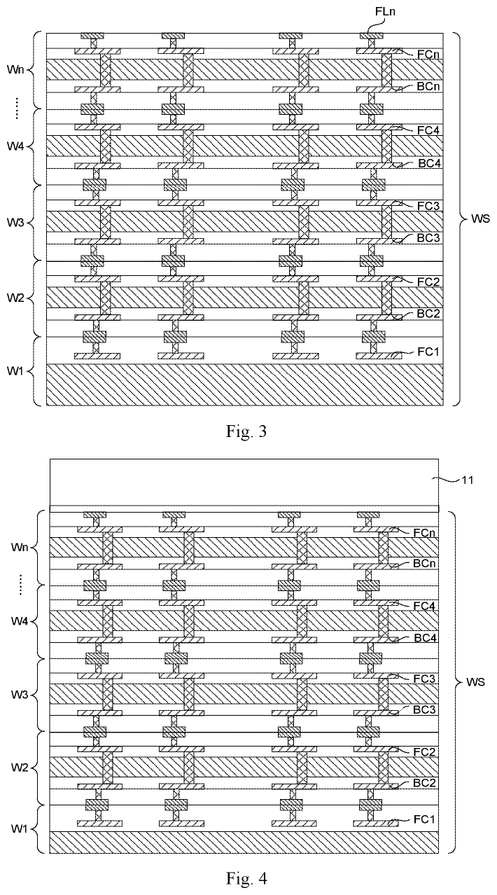

FIG. 3 shows a wafer stack formed using the above method in accordance with one embodiment, denoted by WS. A first device wafer W1 is located at one end of the wafer stack WS, and the n-th device wafer Wn is located at the other end of the wafer stack WS. For example, a top surface of the wafer stack WS may be provided by a front side of the n-th device wafer Wn, and a bottom surface thereof by a back side of the first device wafer W1. On the front side of the n-th device wafer Wn are formed interconnect structures FCn and a bond structure FLn connected to the interconnect structures FCn. The wafer stack WS includes the first device wafer W1, a second device wafer W2, . . . , the n-th device wafer Wn. Each of the n device wafers includes interconnect structures on its front side and a bond structure connected to the interconnect structures on the front side. Optionally, each of the (n−1) device wafers, i.e., the second device wafer W2, . . . , the n-th device wafer further includes interconnect structures on its back side and a bond structure connected to the interconnect structures on the back side. In the wafer stack WS, between any adjacent device wafers, the bond structure on the front side of one device wafer is bonded to the bond structure on the back side of the other device wafer, with electrical connections being established therebetween by metal bond pads.

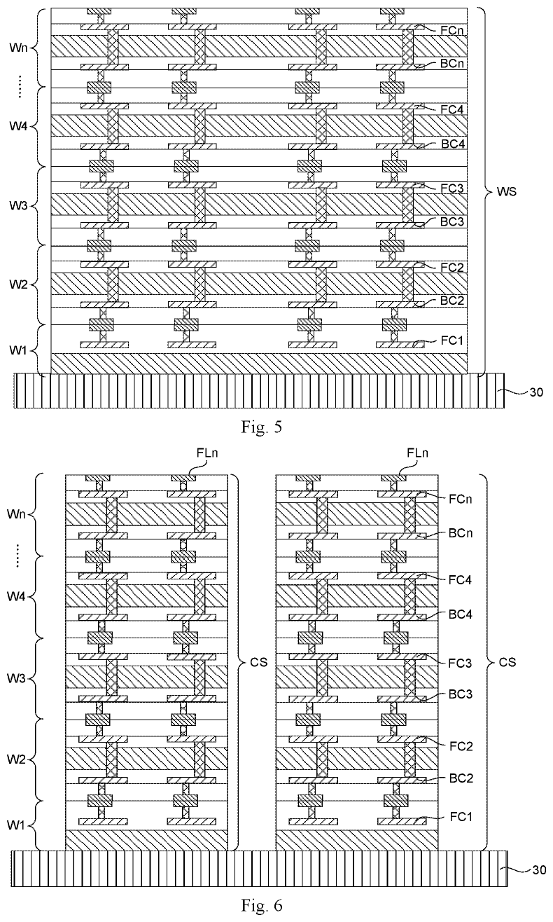

After the wafer stack WS is formed, it is diced in the direction of the thickness thereof to produce individual stacked chip assembly(ies). This process may specifically include: referring to FIG. 4, before the dicing, temporarily bonding the n-th device wafer Wn of the wafer stack WS to a carrier substrate 11 (e.g., adhesive or fusion bonding); then thinning the first device wafer W1 from the back side; referring to FIG. 5, transferring the wafer stack WS with the thinned first device wafer W1 onto a dicing frame 30 (e.g., with the first device wafer W1 in contact with the dicing frame 30) and removing the carrier substrate 11; and referring to FIG. 6, dicing the wafer stack WS in the direction of the thickness thereof to produce at least one stacked chip assembly (denoted by CS). Referring to FIG. 6, each stacked chip assembly CS includes a plurality of stacked and interconnected chips and the bond structure FLn on the front side of a part of the n-th device wafer Wn (this part refers to the part of the n-th device wafer remaining in the stacked chip assembly CS from the dicing process).

In the above, the formation of the stacked chip assembly(ies) has been described as an example. It would be appreciated that the types and number of chips in the stacked chip assembly(ies) used in the subsequent steps may depend on the requirements of the semiconductor device being fabricated, and the stacked chip assembly(ies) used in the subsequent steps may be obtained by dicing one or more wafer stacks.

Referring to FIG. 1, in step S2, a package wafer is provided, and a chip-to-wafer bonding process is carried out to bond the at least one stacked chip assembly CS to a surface of the package wafer.

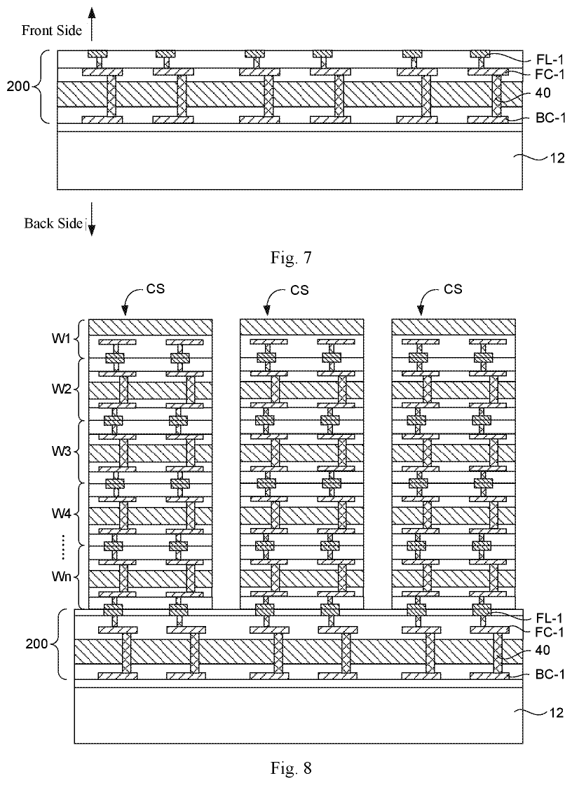

The package wafer may include logic circuits to be interconnected to the stacked chip assembly CS. The package wafer may be, for example, a logic wafer, or a bonded wafer assembly formed by bonding a logic wafer with a memory wafer. Referring to FIG. 7, in some embodiments, the package wafer 200 has a front side on which electronic components are formed and a back side opposite to the front side. On the front side are formed interconnect structures FC-1 and a bond structure FL-1. The bond structure FL-1 is connected to the interconnect structures FC-1 to facilitate the bonding with the stacked chip assembly CS. Before the stacked chip assembly CS is bonded to the package wafer 200, it may be thinned from the back side, and TSVs 40 connected to the interconnect structures FC-1 may be formed in the package wafer 200, and interconnect structures BC-1 connected to the TSVs 40 may be formed on the back side of the package wafer 200. After that, a carrier substrate 12 may be bonded to the back side of the package wafer 200.

Referring to FIG. 8, the chip-to-wafer bonding process may be then performed by bonding the bond structure FLn in the stacked chip assembly CS to the bond structure FL-1 located on the front side of the package wafer 200. This may be accomplished, for example, by hybrid bonding. In some alternative embodiments, the chip-to-wafer bonding may be accomplished by micro-bump bonding or another bonding approach. The stacked chip assembly CS may be bonded to the package wafer 200 in such a manner that the bond structure FLn on the front side of the part of the n-th device wafer Wn is bonded to the package wafer 200 while the back side of the part of the first device wafer W1 in the stacked chip assembly CS faces away from the package wafer 200.

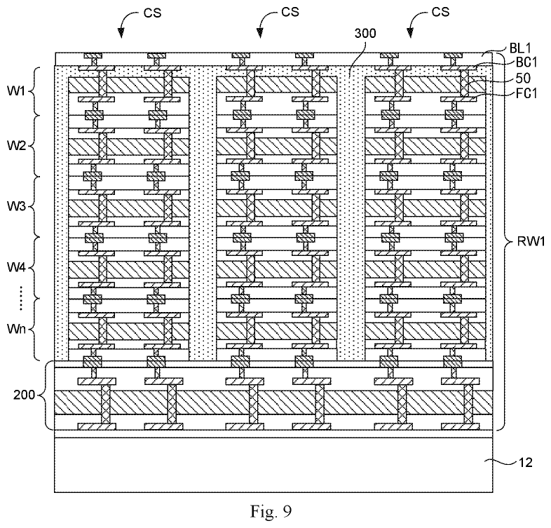

After the at least one stacked chip assembly CS is bonded to the surface of the package wafer 200, a part of the surface of the package wafer 200 is not covered by the stacked chip assembly CS. Referring to FIG. 9, in step S3, wafer reconstruction is performed by forming a first filling cap layer 300 over the surfaces of the package wafer 200 and of the stacked chip assembly CS on the package wafer 200, resulting in the formation of a first reconstructed wafer (denoted by RW1). The first reconstructed wafer includes the package wafer 200 and the stacked chip assembly CS stacked thereon. The formation of the first filling cap layer 300 may include: depositing a dielectric material over the package wafer 200, wherein the dielectric material covers both the part of the surface of the package wafer 200 not covered by the stacked chip assembly CS and the surface of the stacked chip assembly CS, and wherein a top surface of the dielectric material is higher than the top surface of the stacked chip assembly CS, the dielectric material may include one of inorganic materials such as silicon nitride, silicon oxide and silicon oxynitride, or an organic material; a planarization process may be then performed to increase surface flatness on one side of the dielectric material away from the package wafer 200, and the remaining the dielectric material serves as the first filling cap layer 300. The first filling cap layer 300 can function to fix the stacked chip assembly CS on the package wafer 200, and through forming the first filling cap layer 300, the package wafer 200 and the stacked chip assembly CS thereon can overall have wafer-level dimensions.

In some embodiments, the chip-to-wafer bonding and wafer reconstruction processes may be repeated over the first reconstructed wafer RW1 to stack more than two stacked chip assemblies over the package wafer 200.

Referring to FIG. 9, before any subsequent chip-to-wafer bonding process is performed, the method may further include the steps of: forming TSVs 50 connected to an interconnect structure in the first reconstructed wafer RW1 (more precisely, the interconnect structure FC1) on the side of the first reconstructed wafer RW1 away from the package wafer 200 (more precisely, on the side of the back side of the part of the first device wafer W1 in the stacked chip assembly CS); and then optionally forming, on the back side of the part of the first device wafer W1, a bond structure BL1 connected to the TSVs 50. Optionally, before the bond structure BL1 is formed, an interconnect structure BC1 may be formed on the back side of the part of the first device wafer W1. In this way, the bond structure BL1 can be connected to the TSVs 50 by the interconnect structure BC1. The bond structure BL1 may cover each stacked chip assembly CS and the first filling cap layer 300 in the first reconstructed wafer RW. The bond structure BL1 may include a dielectric layer and metal bond pads in the dielectric layer. The bond structure BL1 may have wafer-level dimensions. With the bond structure BL1, another stacked chip assembly CS may be again stacked by chip-to-wafer bonding on the side of the first reconstructed wafer RW1 away from the package wafer 200. The first reconstructed wafer RW1 may include the bond structure BL1.

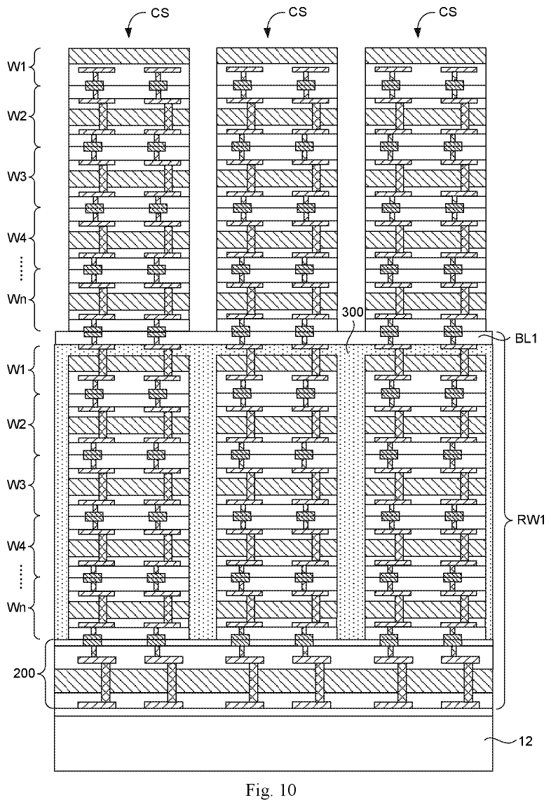

In order to stack more chips, referring to FIG. 10, another chip-to-wafer bonding may be performed to bond at least one stacked chip assembly CS to a surface of the first reconstructed wafer RW1. In this chip-to-wafer bonding process, each stacked chip assembly CS may be bonded to the bond structure BL1, for example, by hybrid bonding or micro-bump bonding. Hybrid bonding is more preferred because it allows denser connections.

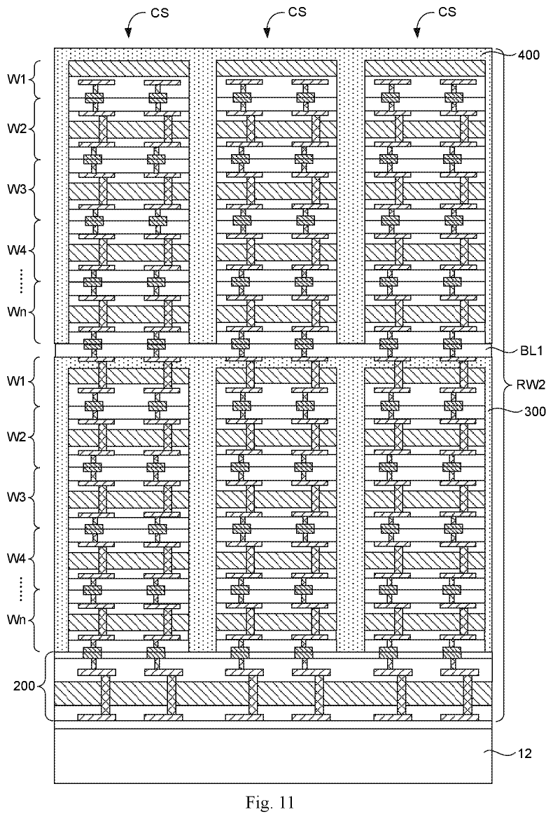

After the at least one stacked chip assembly CS is bonded to the surface of the first reconstructed wafer RW1, referring to FIG. 11, wafer reconstruction may be performed by forming a second filling cap layer 400 over the surfaces of the first reconstructed wafer RW1 and of the stacked chip assembly CS on the first reconstructed wafer RW1, resulting in the formation of a second reconstructed wafer (denoted by RW2). The second reconstructed wafer includes: the package wafer 200 and two layers of stacked chip assembly(ies) CS on the package wafer 200. The formation of the second filling cap layer 400 may include: depositing a dielectric material over the first reconstructed wafer RW1, wherein the dielectric material covers a part of the surface of the first reconstructed wafer RW1 not covered by the stacked chip assembly CS and the surface of the stacked chip assembly CS, and wherein a top surface of the dielectric material is higher than the top surface of the first reconstructed wafer RW1; a planarization process may be then performed to increase surface flatness of the dielectric material away from the first reconstructed wafer RW1, and the remaining dielectric material on the first reconstructed wafer RW1 serves as the second filling cap layer 400.

Depending on the requirements of the semiconductor device being fabricated, after the aforementioned two cycles of chip-to-wafer bonding and wafer reconstruction processes, one or more other such cycles of chip-to-wafer bonding and wafer reconstruction processes may be carried out to stack more than two stacked chip assemblies CS over the package wafer 200.

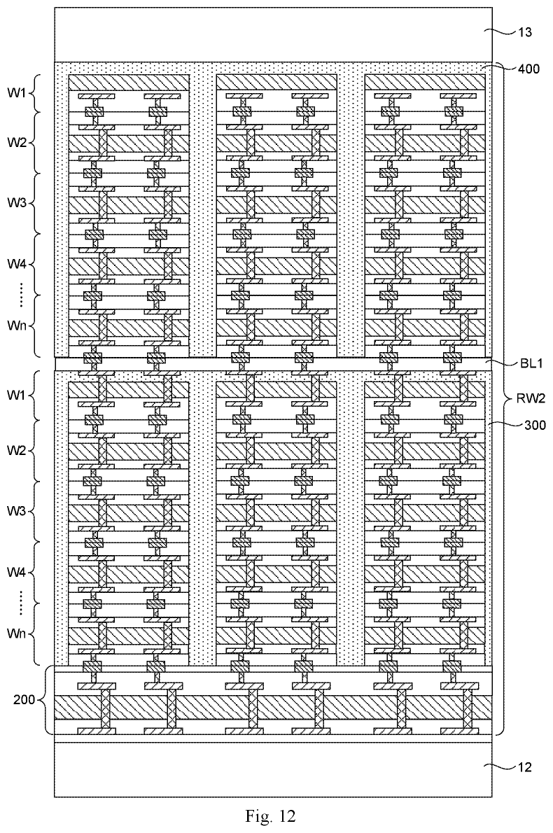

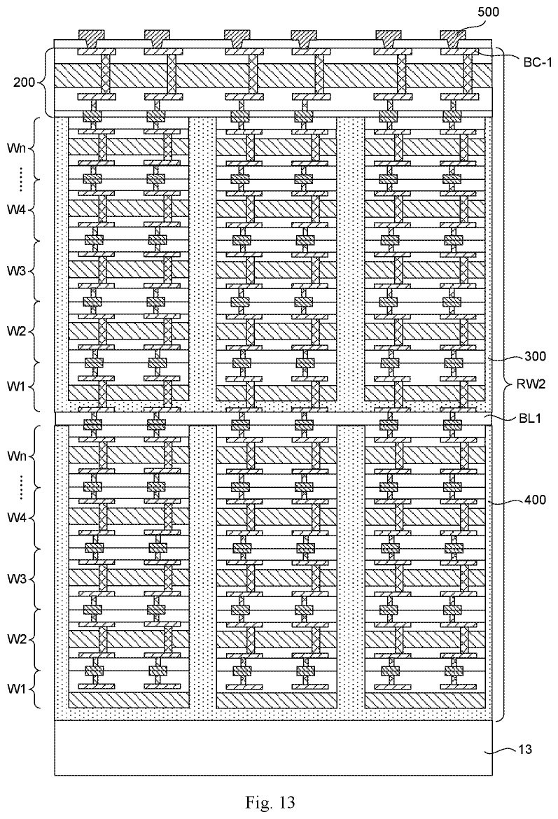

After a desired number of layers of stacked chip assembly(ies) CS have been stacked on the package wafer 200, the method may further include forming metal solder pads on the side of the package wafer 200 away from the stacked chip assemblies CS. Specifically, referring to FIG. 12, after the topmost layer (i.e., the last stacked layer) of stacked chip assembly(ies) CS has been stacked and a corresponding filling cap layer and reconstructed wafer have been formed (only two layers of stacked chip assembly(ies) CS are shown in FIG. 12, in which the layer located farther away from the package wafer 200 is the topmost layer, for example), a carrier substrate 13 may be bonded to the topmost layer of stacked chip assembly(ies) CS, and suitable process(es) may be performed on the side of the package wafer 200. Referring to FIG. 13, the carrier substrate 12 on the side of the package wafer 200 may be removed, and a dielectric layer may be formed on the exposed surface of the package wafer 200. The metal solder pad 500 may be then formed. The metal solder pad 500 extends through the dielectric layer and is connected to the interconnect structure on the package wafer 200 (more precisely, the interconnect structure BC-1 located on the back side of the package wafer 200). The metal solder pads 500 may serve to connect the semiconductor device to an external circuit.

As a result of the above process, at least one layer of stacked chip assembly(ies) CS is stacked on the package wafer 200, and each stacked chip assembly CS includes a plurality of chips stacked and interconnected in the direction of the thickness thereof. With this method, stacked chip assembly(ies) with chip-level dimensions can be stacked with a package wafer with wafer-level dimensions. This enables dense stacking of chips with high process reliability and helps reduce the process cost. The combined use of chip-to-wafer bonding and wafer reconstruction processes can combine wafer-to-wafer stacking with chip-to-wafer stacking. This can achieve improved process efficiency in addition to dense stacking of chips, and helps reduce the process cost and shorten the manufacturing time.

As required, after at least one layer of stacked chip assembly(ies) CS has been stacked on the package wafer 200, the resulting wafer-level structure may be diced in the direction of the thickness thereof into individual chip-level structure(s). Each chip-level structure may include a package substrate obtained by dicing the package wafer 200 and at least one layer of stacked chip assembly(ies) CS stacked on the package substrate. Each layer of stacked chip assembly(ies) CS may include one or more of the aforementioned stacked chip assembly CS.

Embodiments of the present invention also provide a semiconductor device formed using the method according to any one of the above embodiments, which enables dense stacking of chips while helping reduce the process cost and shorten the manufacturing time. Referring to FIG. 13, the semiconductor device includes:
a package substrate obtained, for example, from a package wafer 200, the package substrate having wafer- or chip-level dimensions;
at least one layer of stacked chip assembly(ies) CS stacked on the package substrate, each layer of stacked chip assembly(ies) CS including at least one stacked chip assembly CS, each stacked chip assembly CS including a plurality of chips stacked and interconnected in the direction of the thickness thereof; and
at least one filling cap layer (e.g., a first filling cap layer 300 or a second filling cap layer 400) each surrounding a corresponding layer of the stacked chip assembly(ies) CS.

The semiconductor device may further include metal solder pads 500 formed on the side of the package substrate away from the stacked chip assembly(ies) CS. The package substrate may include a logic circuit, which may be interconnected to a circuit in the stacked chip assembly(ies) CS on the package substrate. The semiconductor device may include high-bandwidth memory (HBM) device, for example.

In some embodiments, the semiconductor device includes at least two layers of stacked chip assembly(ies) CS stacked on the package substrate, in which adjacent layers are bonded together by a bond structure. Referring to FIG. 13, between two adjacent layers of stacked chip assembly(ies), the layer of stacked chip assembly(ies) CS located closer to the package wafer 200 and the respective filling cap layer (e.g., the first filling cap layer 300) are covered by a bond structure with wafer-level dimensions (e.g., a bond structure BL1), and each stacked chip assembly CS in the layer located farther away from the package wafer 200 is bonded to the bond structures with wafer-level dimensions. For the filling cap layers surrounding any adjacent layers of stacked chip assembly(ies) CS, such as the first filling cap layer 300 and the second filling cap layer 400, since the bond structure BL1 with wafer-level dimensions is present between them, they are not in direct contact with each other. That is, the filling cap layers surrounding any adjacent layers of stacked chip assembly(ies) CS are spaced apart from each other.

It is to be noted that the embodiments disclosed herein are described in a progressive manner, with the description of each embodiment focusing on its differences from others. Reference can be made between the embodiments for their identical or similar parts.

The foregoing description is merely that of several preferred embodiments of the present invention and is not intended to limit the scope of the claims of the invention in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of the present invention without departing from the scope of the embodiments are intended to fall within the scope of protection of the invention.

What is claimed is:

1. A method for forming a semiconductor device, comprising:
forming a stacked chip assembly comprising a plurality of chips stacked and interconnected in a direction of a thickness thereof;
providing a package wafer;
bonding at least one of the stacked chip assembly to a surface of the package wafer by performing a chip-to-wafer bonding process; and
obtaining a first reconstructed wafer by performing a wafer reconstruction process through forming a first filling cap layer over the surface of the package wafer and a surface of each stacked chip assembly on the package wafer, wherein the first reconstructed wafer comprises one layer of stacked chip assembly stacked on the package wafer.

2. The method of claim 1, further comprising:
repeating the chip-to-wafer bonding and the wafer reconstruction process over the first reconstructed wafer to stack at least two layers of stacked chip assembly on the package wafer.

3. The method of claim 1, wherein the formation of the stacked chip assembly comprises:
forming a wafer stack by stacking and interconnecting a plurality of device wafers; and
obtaining the stacked chip assembly by dicing the wafer stack in a direction of a thickness thereof.

4. The method of claim 3, wherein each device wafer in the wafer stack has a front side, on which an electronic component is formed, and a back side opposite to the front side, and wherein the front side of each device wafer is oriented in a same direction.

5. The method of claim 4, wherein the wafer stack comprises a first device wafer, a second device wafer, . . . , and an n-th device wafer, which are stacked sequentially in a direction of a thickness thereof, where n is an integer equal to or greater than 2, wherein each of the first, second, . . . , and n-th device wafers comprises interconnect structures on the front side thereof and a bond structure connected to the interconnect structures on the front side, wherein each of the second, . . . , and n-th device wafers further comprises interconnect structures on the back side thereof and a bond structure connected to the interconnect structures on the back side, and wherein between adjacent device wafers, the bond structure on the front side of one of the adjacent device wafers is bonded and electrically connected to the bond structure on the back side of the other one of the adjacent device wafers.

6. The method of claim 5, wherein bonding an m-th device wafer to an (m−1)-th device wafer comprises:
bonding a carrier substrate to the front side of the m-th device wafer;
thinning the m-th device wafer from the back side forming through-silicon vias (TSVs) in the m-th device wafer from the back side;
forming, on the back side of the m-th device wafer, the interconnect structures and the bond structure connected to the interconnect structures, wherein the TSVs connect the interconnect structures on the front side to the interconnect structures on the back side of the m-th device wafer;
bonding the back side of the m-th device wafer to the front side of the (m−1)-th device wafer; and
removing the carrier substrate, where m is equal to or greater than 2 and equal to or smaller than n.

7. The method of claim 5, wherein the first device wafer is thinned from the back side before the wafer stack is diced.

8. The method of claim 5, wherein bonding each stacked chip assembly to the package wafer is accomplished by bonding the bond structure on the front side of the n-th device wafer to the package wafer.

9. The method of claim 8, further comprising:
forming, in the back side of a part of the first device wafer in the first reconstructed wafer, TSVs connected to the interconnect structures on the front side of the part of the first device wafer; and
forming, on the back side of the part of the first device wafer, a bond structure with a wafer-level dimension and connected to the TSVs, in order to allow stacking of the other layer of stacked chip assembly on a side of the first reconstructed wafer away from the package wafer by the chip-to-wafer bonding.

10. The method of claim 1, further comprising, subsequent to the stacking of the at least one stacked chip assembly on the package wafer, forming metal solder pads on a side of the package wafer away from the stacked chip assembly.

11. A semiconductor device, comprising:
a package substrate;
at least one layer of stacked chip assembly stacked on the package substrate, wherein each layer of stacked chip assembly comprises at least one stacked chip assembly, and wherein each stacked chip assembly comprises a plurality of chips stacked and interconnected in a direction of a thickness thereof; and
at least one filling cap layer each surrounding a corresponding layer of stacked chip assembly.

12. The semiconductor device of claim 11, wherein the semiconductor device comprises at least two layers of stacked chip assembly stacked on the package substrate, wherein adjacent layers of stacked chip assembly are bonded by an inter assembly bond structure.

13. The semiconductor device according to claim 12, wherein the stacked chip assembly comprises a first chip, a second chip, . . . , and an n-th chip, which are stacked sequentially in a direction of a thickness thereof, where n is an integer equal to or greater than 2, wherein each of the first, second, . . . , and n-th chips comprises interconnect structures on the front side thereof and an inter-chip bond structure connected to the interconnect structures on the front side, wherein each of the second, . . . , and n-th chips further comprises interconnect structures on the back side thereof and an inter-chip bond structure connected to the interconnect structures on the back side, and wherein between adjacent chips, the inter-chip bond structure on the front side of one of the adjacent chips is bonded and electrically connected to the inter-chip bond structure on the back side of the other one of the adjacent chips.

14. The semiconductor device according to claim 13, wherein each of the inter-chip and inter-assembly bond structures comprises a dielectric layer and a plurality of metal bond pads formed in the dielectric layer.

15. The semiconductor device according to claim 12, wherein the inter-assembly bond structure is of a wafer-level dimension, and in adjacent layers of stacked chip assembly, the layer of stacked chip assembly located closer to the package substrate and the corresponding filling cap layer surrounding thereof are covered by the inter-assembly bond structure.
